(19) United States
(12) Patent Application Publication
(10) Pub. No.: US 2026/0309782 A1
(43) Pub. Date: Oct. 8, 2026

(54) STATE DIAGNOSIS DEVICE, STATE DIAGNOSIS METHOD, AND ABNORMALITY SIGN INFERENCE DEVICE OF ELECTRIC MOTOR

(71) Applicant: Mitsubishi Electric Corporation, Chiyoda-ku, Tokyo (JP)

(72) Inventors: Koki NAGAYAMA, Chiyoda-ku, Tokyo (JP); Toshihiko MIYAUCHI, Chiyoda-ku, Tokyo (JP)

(73) Assignee: Mitsubishi Electric Corporation, Chiyoda-ku, Tokyo (JP)

(21) Appl. No.: 18/998,556

(22) PCT Filed: Sep. 20, 2022
(86) PCT No.: PCT/JP2022/034868

§ 371 Date: Jan. 27, 2025

(51) Int. Cl. G01R 31/34; G01R 19/00; G01R 23/02; G06N 5/04

(52) U.S. Cl. CPC G01R 31/343; G01R 19/0092; G01R 23/02; G06N 5/04

(57) ABSTRACT

A state diagnosis device for an electric motor includes: an analysis circuitry which performs frequency analysis on current data received from a current input circuitry, to calculate an analysis result; a calculation circuitry which detects a plurality of peak intensities of sideband waves about a power supply frequency of the electric motor, from the analysis result; a characteristic peak extraction circuitry which calculates a natural frequency of a belt gear portion from rating information of the electric motor, and extracts, from the plurality of peak intensities detected by the calculation circuitry, the peak intensity of the sideband wave appearing at a position away by a distance of the natural frequency from the power supply frequency of the electric motor as a reference; and a judgment circuitry which compares the peak intensity extracted by the characteristic peak extraction circuitry with a peak intensity threshold calculated from the electric motor operating normally.

### TECHNICAL FIELD

The present disclosure relates to a state diagnosis device, a state diagnosis method, and an abnormality sign inference device for an electric motor.

### BACKGROUND ART

An electric motor is used as a motive power source for a production line device, mechanical equipment, and the like in an industrial plant, and is essential in industry. Therefore, the electric motor is required to be capable of normal and stable operational continuity at all times.

In conventional state diagnosis for an electric motor, an inspection worker visually confirms the operation condition and listens to an operation sound during operation, to confirm whether or not there is abnormality. However, this method relies on the experience or intuition of the inspection worker and therefore there are great variations in diagnosis accuracy. In addition, many of electric motors have high possibilities of causing sudden failure, and therefore there is increasing interest in constant monitoring technology.

Examples of constant monitoring technology for an electric motor include a method of diagnosing abnormality by detecting current applied to an electric motor. For example, Patent Document 1 discloses a rotary-machine-system abnormality detection method in which current applied to an electric motor is measured and is subjected to frequency analysis to detect abnormality of the electric motor.

### CITATION LIST

### Patent Document

Patent Document 1: Japanese Laid-Open Patent Publication No. 2017-181437

### SUMMARY OF THE INVENTION

### Problem to be Solved by the Invention

In the above rotary-machine-system abnormality detection method, detected current information about the electric motor is subjected to fast Fourier transform, and a feature frequency is extracted from the obtained analysis result. Then, from a peak value thereof, a deterioration parameter for determining the deterioration degree for abnormality in a rotary machine system is calculated. Meanwhile, for the deterioration parameter used in abnormality determination for the rotary machine system, it is necessary to calculate a plurality of parameters such as a current effective value, a three-phase current balance, and a current individual harmonic distortion factor.

The present disclosure has been made to solve the above problem, and an object of the present disclosure is to provide a state diagnosis device, a state diagnosis method, and an abnormality sign inference device for an electric motor that can perform state diagnosis for the electric motor using, as a parameter, a peak intensity of a sideband wave due to a natural frequency of a belt gear portion, without the need for calculating a plurality of parameters.

### Means to Solve the Problem

A state diagnosis device for an electric motor according to the present disclosure includes: a current input unit which receives current data detected from the electric motor by a current detector; an analysis unit which performs frequency analysis on the current data received from the current input unit, to calculate an analysis result; a calculation unit which detects a plurality of peak intensities of sideband waves about a power supply frequency of the electric motor, from the analysis result; a characteristic peak extraction unit which calculates a natural frequency of a belt gear portion from rating information of the electric motor, and extracts, from the plurality of peak intensities detected by the calculation unit, the peak intensity of the sideband wave appearing at a position away by a distance of the natural frequency from the power supply frequency of the electric motor as a reference; and a judgment unit which compares the peak intensity extracted by the characteristic peak extraction unit with a peak intensity threshold calculated from the electric motor operating normally, to perform diagnosis for the electric motor.

A state diagnosis method for an electric motor according to the present disclosure includes the steps of: receiving current data detected from an electric motor by a current detector; performing frequency analysis on the received current data, to calculate an analysis result; detecting a plurality of peak intensities of sideband waves about a power supply frequency of the electric motor, from the analysis result; calculating a natural frequency of a belt gear portion from rating information of the electric motor, and extracting, from the plurality of detected peak intensities, the peak intensity of the sideband wave appearing at a position away by a distance of the natural frequency from the power supply frequency of the electric motor as a reference; and comparing the peak intensity with a peak intensity threshold calculated from the electric motor operating normally, to perform diagnosis for the electric motor.

An abnormality sign inference device for an electric motor according to the present disclosure includes: a data acquisition unit which acquires current data and a diagnosis result for the electric motor associated with current data that has not undergone frequency analysis, from the state diagnosis device for the electric motor described above; a trained model generation unit which learns the current data acquired by the data acquisition unit on the basis of the diagnosis result, to generate a trained model; and a current data inference unit which infers an abnormality sign of the electric motor from the current data newly acquired from the data acquisition unit, using the trained model, and outputs an inference result.

### Effect of the Invention

In the state diagnosis device and the state diagnosis method for the electric motor according to the present disclosure, the characteristic peak extraction unit extracts peak intensities of sideband waves due to a belt gear frequency from peak intensities of sideband waves detected from a spectrum waveform by the calculation unit, and the judgment unit compares the extracted peak intensities with a peak intensity threshold, to perform state diagnosis for the electric motor. Thus, an effect of decreasing the number of parameters needed in diagnosis and shortening a time taken for diagnosis is provided. In the abnormality sign inference device for the electric motor according to the present disclosure, before the state diagnosis device for the electric motor diagnoses that there is abnormality in the electric motor, the abnormality sign inference device infers an abnormality sign from current data and outputs presence/absence of an abnormality sign to the monitoring device, whereby it is possible to perform maintenance of the electric motor in a planned manner.

### BRIEF DESCRIPTION OF THE DRAWINGS

FIG. 1 shows an entire system configuration of a state diagnosis device for an electric motor according to embodiment 1.

FIG. 2 shows a hardware configuration of the state diagnosis device for the electric motor according to embodiment 1.

FIG. 3 shows a configuration of a calculation processing unit of the state diagnosis device for the electric motor according to embodiment 1.

FIG. 4 shows a connection relationship among the electric motor, a belt gear portion, and load equipment with respect to the state diagnosis device for the electric motor according to embodiment 1.

FIG. 5 is a flowchart showing a processing procedure in learning of the state diagnosis device for the electric motor according to embodiment 1.

FIG. 6 is a flowchart showing a processing procedure in diagnosis by the state diagnosis device for the electric motor according to embodiment 1.

FIG. 7 is a flowchart showing a processing procedure of frequency analysis in the state diagnosis device for the electric motor according to embodiment 1.

FIG. 8 shows comparison of analysis results in a normal case and an abnormal case of the electric motor.

FIG. 9 shows a configuration of a calculation processing unit of a state diagnosis device for an electric motor according to embodiment 2.

FIG. 10 is a flowchart showing a processing procedure in learning of the state diagnosis device for the electric motor according to embodiment 2.

FIG. 11 is a flowchart showing a processing procedure in diagnosis by the state diagnosis device for the electric motor according to embodiment 2.

FIG. 12 shows an entire system configuration of a state diagnosis device for an electric motor according to embodiment 3.

FIG. 13 shows an entire system configuration of an abnormality sign inference device for an electric motor according to embodiment 4.

FIG. 14 is a flowchart showing a processing procedure in learning of an abnormality sign inference device for the electric motor according to embodiment 4.

FIG. 15 is a flowchart showing a processing procedure in usage of the abnormality sign inference device for the electric motor according to embodiment 4.

### DESCRIPTION OF EMBODIMENTS

Hereinafter, embodiments will be described in detail with reference to the drawings. The embodiments described below are merely examples. Any of the embodiments may be combined as appropriate, when implemented.

### Embodiment 1

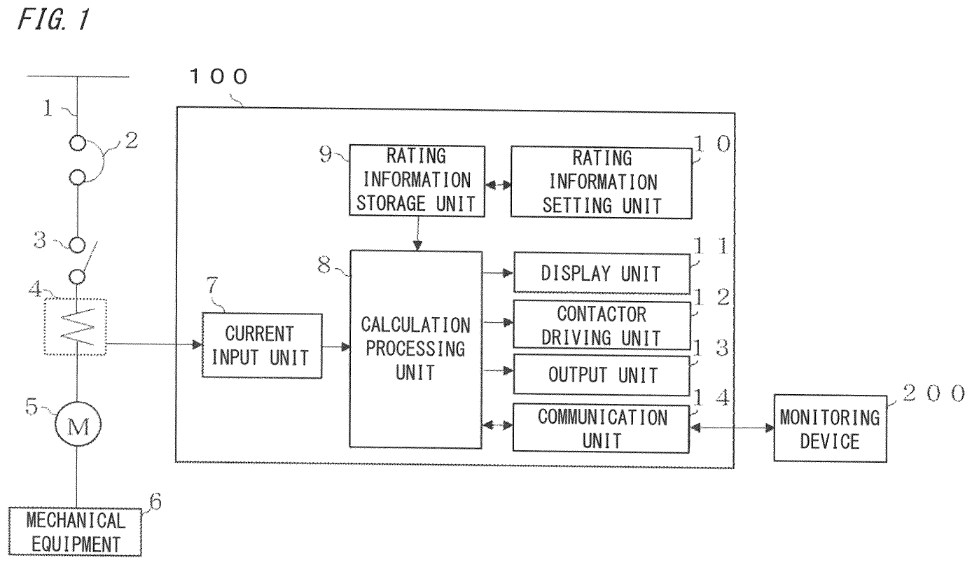

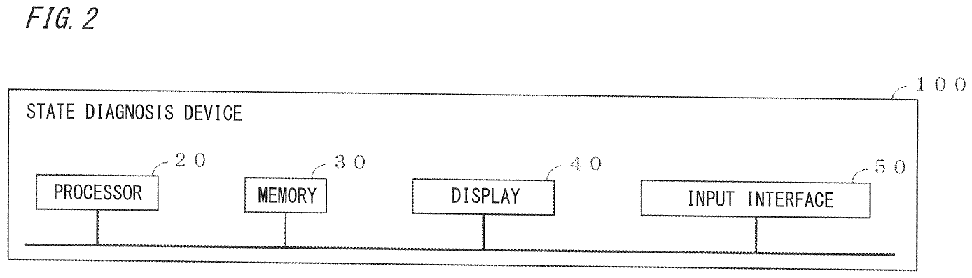

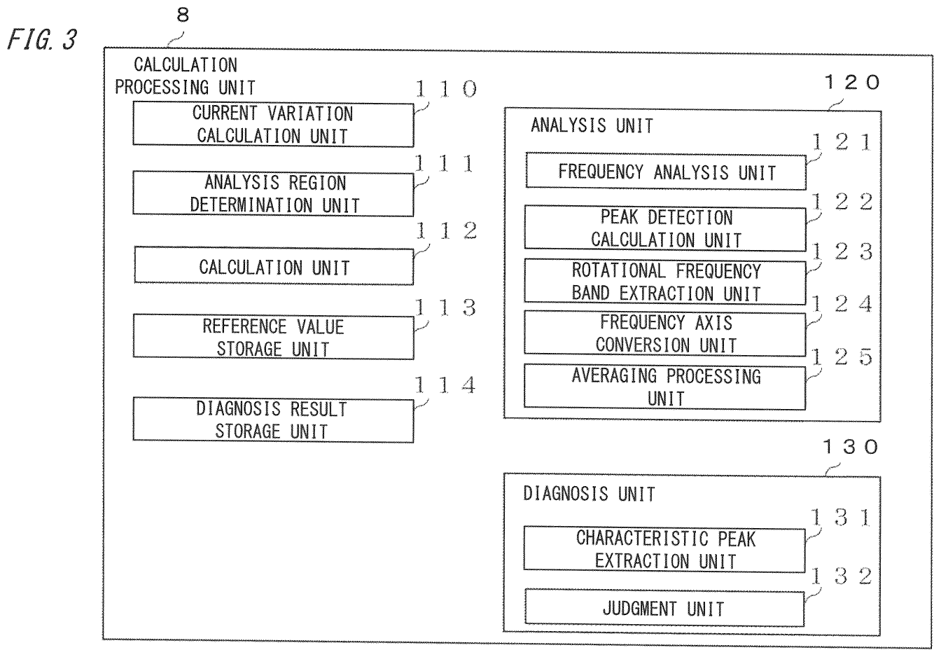

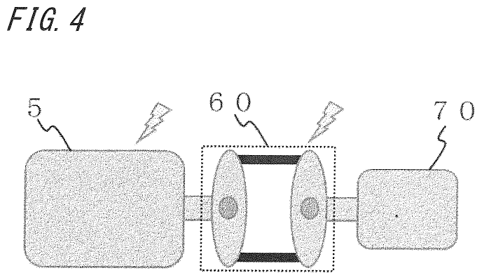

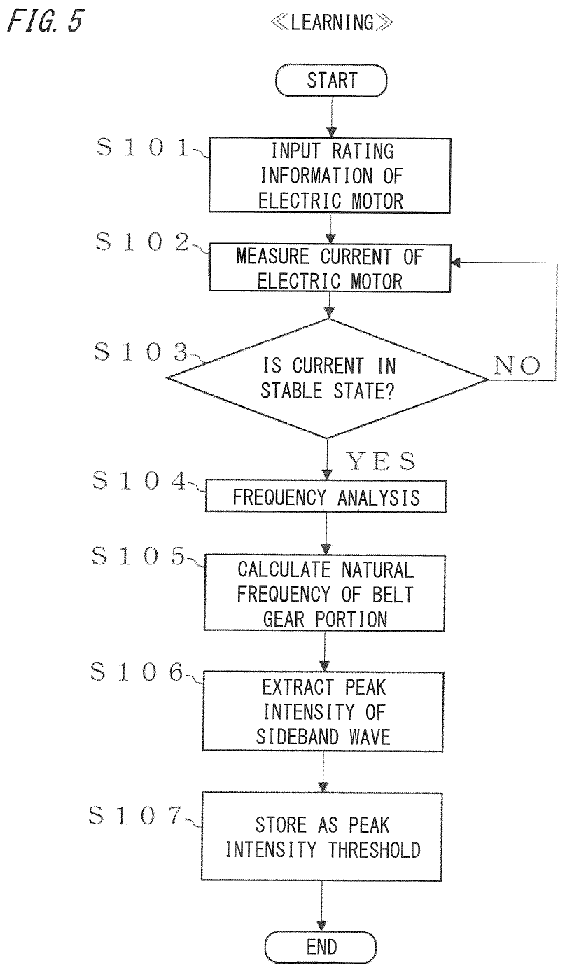

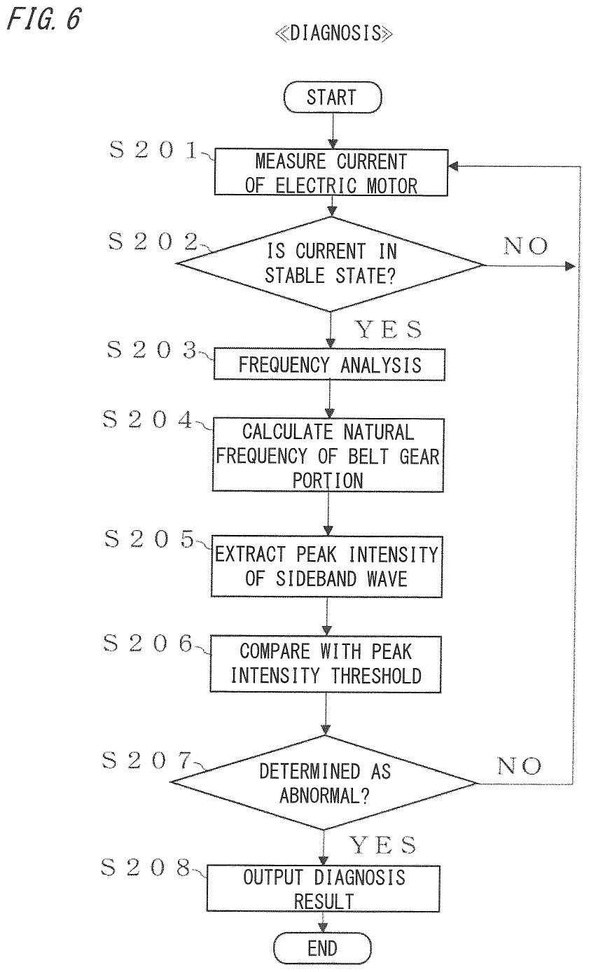

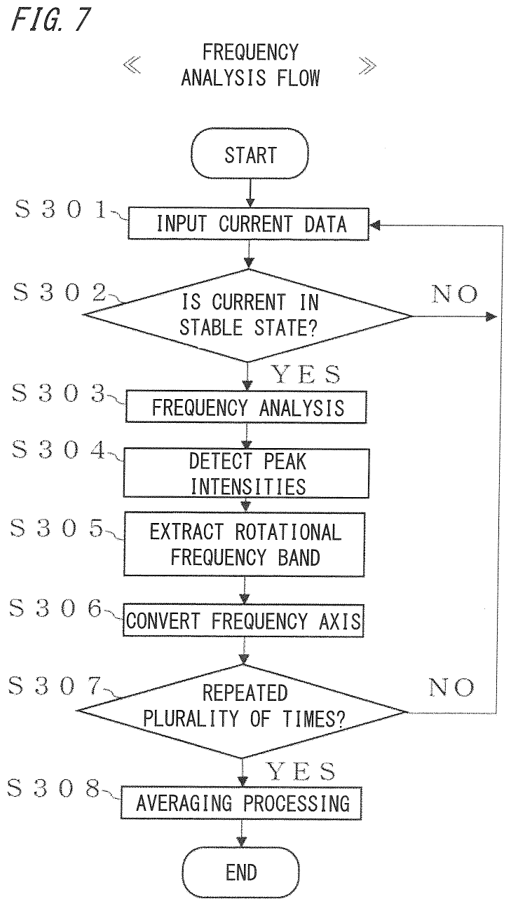

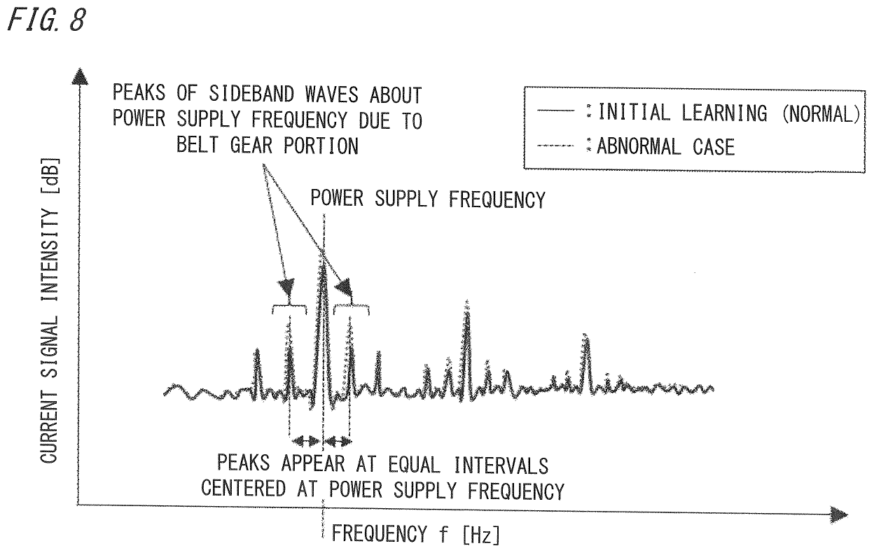

FIG. 1 is an entire system configuration of a state diagnosis device for an electric motor according to embodiment 1. FIG. 2 shows a hardware configuration of the state diagnosis device for the electric motor according to embodiment 1. FIG. 3 shows a configuration of a calculation processing unit of the state diagnosis device for the electric motor according to embodiment 1. FIG. 4 shows a connection relationship among the electric motor, a belt gear portion, and load equipment with respect to the state diagnosis device for the electric motor according to embodiment 1. FIG. 5 is a flowchart showing a processing procedure in learning of the state diagnosis device for the electric motor according to embodiment 1. FIG. 6 is a flowchart showing a processing procedure in diagnosis by the state diagnosis device for the electric motor according to embodiment 1. FIG. 7 is a flowchart showing a processing procedure of frequency analysis in the state diagnosis device for the electric motor according to embodiment 1. FIG. 8 shows comparison of analysis results in a normal case and an abnormal case of the electric motor.

As shown in FIG. 1, a circuit breaker 2, an electromagnetic contactor 3, a current detector 4, and an electric motor 5 are connected to the main circuit 1. The circuit breaker 2 prevents overcurrent from flowing to the electric motor 5 when abnormality has occurred in a grid. The electromagnetic contactor 3 serves as a switch for turning on/off the electric motor 5. The current detector 4 detects load current of the main circuit 1 and outputs the detected current to a current input unit 7 of a state diagnosis device 100. The electric motor 5 is connected to mechanical equipment 6 composing a production line or the like, and is operated and driven by a power conversion device or the like (not shown). The electric motor 5 is, for example, a three-phase induction electric motor, but is not limited thereto.

The state diagnosis device 100 includes the current input unit 7, a calculation processing unit 8, a rating information storage unit 9, a rating information setting unit 10, a display unit 11, a contactor driving unit 12, an output unit 13, and a communication unit 14. The current input unit 7 receives current data detected by the current detector 4, and outputs the current data to the calculation processing unit 8. The calculation processing unit 8 analyzes the current data inputted from the current input unit 7 and calculates a parameter to be used for diagnosis for the electric motor 5, to perform abnormality diagnosis for the electric motor 5. The details of the calculation processing unit 8 will be described later.

FIG. 2 shows a hardware configuration of the state diagnosis device 100 according to the present disclosure. The state diagnosis device 100 is formed by a processor 20 such as a central processing unit (CPU), a memory 30 such as a random access memory (RAM), a display 40, and an input interface (I/F) 50. The calculation processing unit 8 is implemented by the processor 20 executing a program stored in the memory 30. This may be implemented by cooperation of a plurality of processors 20, for example.

Rating information such as a power supply frequency, a rated output, rated current, the number of poles, and a rated rotational speed of the electric motor 5 are inputted to the rating information setting unit 10 in advance. The rating information is basic information written in a catalog, a manual, or the like of a manufacturing company for the electric motor 5. In the present embodiment, a case where the number of electric motors 5 to be diagnosed is one is shown, but in a case of diagnosing a plurality of electric motors 5, the rating information of each electric motor 5 is inputted to the rating information setting unit 10 in advance.

The rating information storage unit 9 stores the rating information inputted to the rating information setting unit 10, and outputs the rating information to the calculation processing unit 8 as necessary. In FIG. 1, a case where the rating information storage unit 9 and the rating information setting unit 10 are provided separately from each other is shown, but the configuration is not limited thereto. The rating information storage unit 9 and the rating information setting unit 10 may be provided together and may be configured to store the rating information of the electric motor 5 and output the rating information to the calculation processing unit 8 at the time of analysis on the current data inputted from the current input unit 7.

The rating information storage unit 9 and the rating information setting unit 10 may not necessarily be provided to the state diagnosis device 100, and may be provided outside. In this case, the rating information of the electric motor 5 may be stored in an external server, for example, and may be inputted to the calculation processing unit 8 at the time of diagnosis for the electric motor 5.

The display unit 11, the contactor driving unit 12, the output unit 13, and the communication unit 14 are connected to the calculation processing unit 8. When abnormality of the electric motor 5 is detected by the calculation processing unit 8, the display unit 11 displays detected current data and displays an abnormal state, warning, and the like. Warning may be performed by an alarm or the like, instead of display.

When abnormality of the electric motor 5 is detected by the calculation processing unit 8, the contactor driving unit 12 outputs a control signal for opening/closing the electromagnetic contactor 3. The output unit 13 outputs an abnormal state, warning, and the like to a management department for a production line. The communication unit 14 transmits an abnormal state of the electric motor 5 and the like via a network to a monitoring device 200 such as a PC or a tablet terminal serving as an external master device for the entire state diagnosis device 100. A method for data transmission from the communication unit 14 to the monitoring device 200 may be a wired method or a wireless method.

Next, the configuration of the calculation processing unit 8 will be described with reference to FIG. 3. As shown in FIG. 3, the calculation processing unit 8 includes a current variation calculation unit 110, an analysis region determination unit 111, a calculation unit 112, a reference value storage unit 113, a diagnosis result storage unit 114, an analysis unit 120, and a diagnosis unit 130. The analysis unit 120 includes a frequency analysis unit 121, a peak detection calculation unit 122, a rotational frequency band extraction unit 123, a frequency axis conversion unit 124, and an averaging processing unit 125. The diagnosis unit 130 includes a characteristic peak extraction unit 131 and a judgment unit 132.

The current variation calculation unit 110 calculates presence/absence of variation in current data inputted from the current input unit 7 and judges whether or not the current data is in a stable state. Specifically, analysis of statistical variation in the current data is performed. For example, an analysis method such as Mahalanobis distance is used to judge whether or not the electric motor 5 is in a stable state.

The current variation calculation unit 110 stores a region determination threshold acquired from the electric motor 5 operating normally in advance, as a threshold for judging whether or not the current data is in a stable state. For example, for the region determination threshold, current data of a plurality of electric motors 5 are acquired in advance, and the region determination threshold is selected in a range smaller than a standard deviation of the acquired current data. Alternatively, current data of the electric motor 5 to be diagnosed may be collected during a certain period, and the region determination threshold may be set using a standard deviation or the like of the collected current data as a reference. The region determination threshold may be stored in the rating information storage unit 9 together with the rating information of the electric motor 5, instead of being stored in the current variation calculation unit 110.

The analysis region determination unit 111 compares a calculation result of the current variation calculation unit 110 with the region determination threshold calculated in advance from the electric motor operating normally, to determine an analysis region. That is, from the current data inputted from the current input unit 7, the analysis region determination unit 111 extracts a region where the current data is in a stable state, to determine an analysis region where the analysis unit 120 executes analysis. Specifically, a region where statistical variation obtained through calculation by the current variation calculation unit 110 is not greater than a threshold set in advance is determined as a region where the current data is in a stable state, i.e., the analysis region.

The analysis unit 120 includes the frequency analysis unit 121, the peak detection calculation unit 122, the rotational frequency band extraction unit 123, the frequency axis conversion unit 124, and the averaging processing unit 125.

The frequency analysis unit 121 performs frequency analysis on current data inputted from the current input unit 7, in the analysis region extracted by the analysis region determination unit 111, to calculate a spectrum waveform which is an analysis result. The current data is analyzed by, for example, current fast Fourier transform (FFT) analysis, discrete Fourier transform analysis, or the like.

The peak detection calculation unit 122 detects a plurality of sideband waves about the power supply frequency from the spectrum waveform obtained through frequency analysis by the frequency analysis unit 121, and calculates peak intensities of the detected sideband waves.

Specifically, the peak detection calculation unit 122 extracts parts where sharp slopes are inverted, through first-order, second-order, and third-order differential calculations, from the detected sideband waves about the power supply frequency, to calculate peak intensities. In this way, in calculating peak intensities, differential calculation is performed up to third order, whereby small peak intensities can also be detected.

The rotational frequency band extraction unit 123 calculates the rotational frequency from the rating information of the electric motor 5, and extracts peak intensities of sideband waves about the power supply frequency that appear at positions away from the power supply frequency of the electric motor 5 by a distance of the rotational frequency, from the peak intensities of the plurality of sideband waves detected by the peak detection calculation unit 122. Specifically, the rotational frequency band extraction unit 123 calculates the rotational frequency from the rated rotational speed in the rating information stored in the rating information storage unit 9, and using the calculated rotational frequency, extracts sideband waves having approximately equal peak intensities and appearing at positions away by a distance of the rotational frequency toward both of high-frequency and low-frequency sides from the power supply frequency.

Regarding calculation of the rotational frequency, the rotational frequency band extraction unit 123 calculates the rotational frequency, using the rating information stored in the rating information storage unit 9, by the following Formula (1). Here, the rotational frequency is denoted by fn, the power supply frequency is denoted by f, the number of poles is denoted by P, and a slip of the electric motor 5 is denoted by s.

$$( Mathematical 1 )$$

$$fn = ( 2 \times f ) / P \times ( 1 - s ) \qquad Formula ( 1 )$$

As described above, the rotational frequency band extraction unit 123 calculates the rotational frequency, using the Formula (1), and extracts peak intensities of sideband waves about the power supply frequency that appear in rotational frequency bands, from the peak intensities of the sideband waves calculated by the peak detection calculation unit 122. Here, the rotational frequency bands refer to frequencies at positions away from the power supply frequency of the electric motor 5 by a distance of the rotational frequency, and refer to two positions that are a position away from the power supply frequency toward the low-frequency side by a distance of the rotational frequency and a position away from the power supply frequency toward the high-frequency side by a distance of the rotational frequency.

The frequency axis conversion unit 124 calculates a correction value for aligning the frequency axes of the spectrum waveforms obtained through frequency analysis, and corrects the spectrum waveforms calculated by the frequency analysis unit 121. In a spectrum waveform obtained by performing frequency analysis on current data, the rotational frequency shifts depending on the state of load torque of the electric motor 5. Therefore, in order to ensure that the averaging processing unit 125 described later can perform averaging processing with a plurality of spectrum waveforms accurately overlapped without shift, the frequency axis conversion unit 124 calculates a correction value for spectrum waveforms and performs correction so as to align the frequency axes of the spectrum waveforms.

The correction value calculated by the frequency axis conversion unit 124 will be described. In accordance with the state of load torque of the electric motor 5, a slip of the electric motor 5 changes, and a rotational frequency fn calculated by Formula (1) in the rotational frequency band extraction unit 123 also changes in accordance with the slip of the electric motor 5.

For example, in a case where a power supply frequency f is 60 Hz and the number of poles P is 4, the rotational frequency fn is calculated by the following Formula (2), under the condition that there is no slip (s=0).

$$( Mathematical 2 )$$

$$fn = ( 2 \times 60 ) / 4 \times ( 1 - 0 ) = 30 Hz \qquad Formula ( 2 )$$

On the other hand, in a case where the slip is 2% depending on the state of load torque of the electric motor 5, the rotational frequency fn is calculated by the following Formula (3).

$$( Mathematical 3 )$$

$$fn = ( 2 \times 60 ) / 4 \times ( 1 - 0.02 ) = 30.6 Hz \qquad Formula ( 3 )$$

Thus, depending on the state of load torque of the electric motor 5, the value of the rotational frequency fn calculated using Formula (1) changes. Therefore, considering shift due to a slip as described above, the frequency axis conversion unit 124 performs correction for shift from a reference corresponding to a state in which there is no slip, i.e., a no-load state. Specifically, in a case where the slip is 2%, shift of 0.06 Hz occurs as compared to the rotational frequency in a no-load state, according to Formula (3). In such a case, the frequency axis conversion unit 124 corrects the spectrum waveforms with the correction value set at 0.06 Hz. Thus, using the rotational frequency in a state in which there is no slip in the electric motor 5, i.e., a no-load state, as a reference, the frequency axis conversion unit 124 corrects each of the spectrum waveforms by a correction value corresponding to a difference from the reference, in a case where the rotational frequency calculated by the rotational frequency band extraction unit 123 shifts from the reference.

The averaging processing unit 125 performs processing of averaging a plurality of spectrum waveforms corrected by the frequency axis conversion unit 124. Thus, after the frequency axis conversion unit 124 calculates a correction value for aligning the rotational frequency and corrects each spectrum waveform, averaging processing is performed in a state in which the plurality of spectrum waveforms with the frequency axes aligned are overlapped, whereby the plurality of spectrum waveforms can be averaged in an accurately overlapped state.

The calculation unit 112 detects a plurality of peak intensities of sideband waves about the power supply frequency from the analysis result of the analysis unit 120. Specifically, the calculation unit 112 detects a plurality of peak intensities of sideband waves about the power supply frequency from the spectrum waveform having undergone the averaging processing in the averaging processing unit 125. The output result of the calculation unit 112 is outputted to the characteristic peak extraction unit 131 of the diagnosis unit 130.

The diagnosis unit 130 includes the characteristic peak extraction unit 131 and the judgment unit 132.

FIG. 4 shows transfer of vibration to a belt gear portion 60 when abnormality has occurred in the electric motor 5. Here, the belt gear portion 60 includes a belt and gears connecting the electric motor 5 and the load equipment 70.

The characteristic peak extraction unit 131 extracts peak intensities of sideband waves due to the natural frequency (hereinafter, referred to as belt gear frequency) which appear when abnormality has occurred in the belt gear portion 60 connecting the electric motor 5 and the load equipment 70. That is, the characteristic peak extraction unit 131 extracts peak intensities of sideband waves due to the belt gear frequency from the plurality of peak intensities of the sideband waves detected by the calculation unit 112. The belt gear frequency, which is the natural frequency appearing when abnormality has occurred in the belt gear portion 60, may be the natural frequency when abnormality has occurred in the belt, or may be the natural frequency appearing when abnormality has occurred in the gears.

The way of extraction will be described. The characteristic peak extraction unit 131 calculates the belt gear frequency on the basis of the rating information stored in the rating information storage unit 9, and extracts sideband waves having approximately equal peak intensities and appearing at positions away by a distance of the belt gear frequency toward both of high-frequency and low-frequency sides from the power supply frequency.

The belt gear frequency is calculated using the rating information of the electric motor 5 stored in the rating information storage unit 9, by the following Formula (4). Here, the belt gear frequency is denoted by F, the power supply frequency is denoted by f, and the number of poles is denoted by P.

$$( Mathematical 4 )$$

$$F = ( 2 \times f ) / P \times ( speed reduction ratio ) \qquad Formula ( 4 )$$

For example, in a case where the rating information of the electric motor 5 prescribes that the power supply frequency f is 60 Hz, the number of poles P is 4, and the speed reduction ratio is 1:3, the belt gear frequency F can be calculated as (2×60)/4×(⅓)=10 Hz by Formula (1).

Thus, in the above example, the characteristic peak extraction unit 131 extracts sideband waves having approximately equal peak intensities and appearing at positions away by 10 Hz toward both of high-frequency and low-frequency sides from the power supply frequency. That is, sideband waves having approximately equal peak intensities are extracted on both of high-frequency and low-frequency sides of the power supply frequency.

FIG. 4 shows a connection relationship among the electric motor 5, the belt gear portion 60, and load equipment 70. As shown in FIG. 4, when abnormality has occurred in the electric motor 5, vibration of the electric motor 5 transfers to the belt gear portion 60 connected to the electric motor 5. Also when abnormality has occurred in the load equipment 70, vibration of the load equipment 70 transfers to the belt gear portion 60. Therefore, by the characteristic peak extraction unit 131 extracting sideband waves due to the belt gear frequency of the belt gear portion 60, it is possible to detect not only abnormality of the belt gear portion 60 but also abnormality of the electric motor 5 and the load equipment 70 connected to the belt gear portion 60.

The judgment unit 132 compares the peak intensities of the sideband waves due to the belt gear frequency extracted by the characteristic peak extraction unit 131 with a peak intensity threshold which is a peak intensity of a sideband wave calculated using current data of the electric motor 5 operating normally and which is stored in the reference value storage unit 113 in advance, to diagnose whether or not there is abnormality in the electric motor 5. A specific processing procedure in diagnosis will be described later with reference to FIG. 7.

In a case where the electric motor 5 is diagnosed as abnormal by the judgment unit 132 of the diagnosis unit 130, the calculation processing unit 8 outputs information for notifying the display unit 11, the contactor driving unit 12, the output unit 13, and the communication unit 14 about abnormality, and the diagnosis result is stored into the diagnosis result storage unit 114. The diagnosis result of the electric motor 5 may be stored in the diagnosis result storage unit 114 so as to be associated with the current data that has not undergone frequency analysis by the frequency analysis unit 121.

The reference value storage unit 113 stores a peak intensity of a sideband wave due to the belt gear frequency acquired in advance from current data of the electric motor 5 operating normally, as a reference value used for diagnosis for the electric motor 5, i.e., the peak intensity threshold. The peak intensity threshold may be stored together with the rating information in the rating information storage unit 9. A specific processing procedure thereof will be described below with reference to FIG. 5.

Next, processing procedures in learning and diagnosis will be described with reference to FIG. 5 to FIG. 7.

First, the processing procedure in learning will be described with reference to FIG. 5. FIG. 5 is a flowchart showing a calculation procedure for the peak intensity threshold to be used at the time of performing comparison with peak intensities of sideband waves.

In step S101, the rating information of the electric motor 5 operating normally is inputted to the rating information setting unit 10 and stored in the rating information storage unit 9. The rating information of the electric motor 5 may be inputted to the rating information storage unit 9 and stored therein. In a case where there are a plurality of electric motors 5 to be diagnosed, the rating information of each electric motor 5 is inputted and stored.

In step S102, current of the electric motor 5 to be diagnosed, which is acquired by the current detector 4, is inputted to the current input unit 7.

In step S103, the current variation calculation unit 110 calculates variation in the current data inputted to the current input unit 7, i.e., whether or not the current data is in a stable state, and the analysis region determination unit 111 extracts a region where the current data is in a stable state and determines the region as an analysis region where frequency analysis is to be performed. The current variation calculation unit 110 performs calculation on the current data and comparison with the region determination threshold. If the region determination threshold is not satisfied, the current data is judged to be in an unstable state and the process returns to step S102. If the current data is judged to be in a stable state, the process proceeds to step S104.

In step S104, the frequency analysis unit 121 performs frequency analysis on the current data in the analysis region judged to be in a stable state, to calculate a spectrum waveform which is an analysis result. The spectrum waveform which is an analysis result obtained through frequency analysis is outputted to the calculation unit 112. The details of frequency analysis in step S104 will be described later with reference to FIG. 7.

In step S105, the characteristic peak extraction unit 131 calculates the belt gear frequency due to the belt gear portion 60 corresponding to the electric motor 5 from the information of the electric motor 5 stored in the rating information storage unit 9.

In step S106, the characteristic peak extraction unit 131 extracts peak intensities of sideband waves due to the belt gear frequency from the peak intensities of the sideband waves inputted from the calculation unit 112. That is, using the belt gear frequency calculated in step S105, the characteristic peak extraction unit 131 extracts sideband waves having approximately equal peak intensities and appearing at positions away by a distance of the belt gear frequency toward both of high-frequency and low-frequency sides from the power supply frequency.

In step S107, the reference value storage unit 113 stores the peak intensity of the sideband waves extracted by the characteristic peak extraction unit 131 in step S106, as a threshold to be used in diagnosis, i.e., the peak intensity threshold.

Next, the processing procedure in diagnosis will be described with reference to FIG. 6. FIG. 6 is a flowchart showing the processing procedure in diagnosis.

In step S201, current of the electric motor 5 to be diagnosed, which is acquired by the current detector 4, is inputted to the current input unit 7.

In step S202, the current variation calculation unit 110 calculates variation in the current data inputted to the current input unit 7, i.e., whether or not the current data is in a stable state, and the analysis region determination unit 111 extracts a region where the current data is in a stable state and determines the region as an analysis region where frequency analysis is to be performed. The current variation calculation unit 110 performs calculation on the current data and comparison with the region determination threshold. If the region determination threshold is not satisfied, the current data is judged to be in an unstable state and the process returns to step S201. If the current data is judged to be in a stable state, the process proceeds to step S203.

In step S203, the frequency analysis unit 121 performs frequency analysis on the current data in the analysis region judged to be in a stable state in step S202, to calculate a spectrum waveform which is an analysis result. The spectrum waveform which is an analysis result obtained through frequency analysis is inputted to the calculation unit 112. The details of frequency analysis will be described later with reference to FIG. 7.

In step S204, the characteristic peak extraction unit 131 calculates the belt gear frequency due to the belt gear portion 60 of the electric motor 5 to be diagnosed, from the rating information of the electric motor 5 stored in the rating information storage unit 9.

In step S205, the characteristic peak extraction unit 131 extracts peak intensities of sideband waves due to the belt gear frequency from peak intensities of sideband waves inputted from the calculation unit 112. That is, using the belt gear frequency calculated in step S105, the characteristic peak extraction unit 131 extracts sideband waves having approximately equal peak intensities and appearing at positions away by a distance of the belt gear frequency toward both of high-frequency and low-frequency sides from the power supply frequency.

In step S206, the judgment unit 132 compares the peak intensities of the sideband waves due to the belt gear frequency extracted in step S205, with the peak intensity threshold stored in the reference value storage unit 113.

In step S207, as a result of comparison between the peak intensities of the sideband waves due to the belt gear frequency and the peak intensity threshold stored in the reference value storage unit 113, if the peak intensities of the sideband waves satisfy the peak intensity threshold, the judgment unit 132 judges that there is abnormality in the electric motor 5, and the process proceeds to step S208. On the other hand, if the peak intensity threshold is not satisfied, the judgment unit 132 judges that the electric motor 5 is normal, and the process returns to step S201.

In step S208, the judgment unit 132 outputs the diagnosis result to the display unit 11, the contactor driving unit 12, the output unit 13, and the communication unit 14. In addition, the diagnosis result is stored into the diagnosis result storage unit 114.

Next, the frequency analysis in steps S104 and S203 will be described in detail with reference to FIG. 7. FIG. 7 shows a flow of the frequency analysis. The process shown in steps S301 to S308 in FIG. 7 corresponds to the process in steps S101 to S103 in FIG. 5 and the process in steps S201 to S203 in FIG. 6. In FIG. 7, step S301 is the same as steps S102 and S201, and step S302 is the same as steps S103 and S202, and therefore the description thereof is omitted.

In step S303, the frequency analysis unit 121 performs frequency analysis on the current data in the analysis region judged to be in a stable state, to calculate a spectrum waveform which is an analysis result. The frequency analysis unit 121 inputs the calculated spectrum waveform to the peak detection calculation unit 122.

In step S304, the peak detection calculation unit 122 detects a plurality of peak intensities of sideband waves about the power supply frequency from the spectrum waveform which is a result of frequency analysis inputted from the frequency analysis unit 121.

In step S305, the rotational frequency band extraction unit 123 extracts peak intensities of sideband waves appearing in the rotational frequency bands, from the plurality of peak intensities of sideband waves detected by the peak detection calculation unit 122. The rotational frequency band extraction unit 123 extracts peak intensities of sideband waves appearing in the rotational frequency bands on both of high-frequency and low-frequency sides of the power supply frequency. Extraction of the peak intensities is performed by calculating the rotational frequency from the rated rotational speed in the rating information stored in the rating information storage unit 9 and extracting sideband waves appearing at positions away by a distance of the rotational frequency toward both sides from the power supply frequency as a center.

In step S306, in order to reduce the influence of shift of the rotational frequency due to load torque, the frequency axis conversion unit 124 calculates a correction value for the spectrum waveform, and performs correction for aligning the frequency axis of the spectrum waveform, using the calculated correction value. Thus, shift of the rotational frequency depending on the state of load torque can be eliminated.

In step S307, the averaging processing unit 125 repeats steps S301 to S306 a plurality of times, to collect a plurality of spectrum waveforms that have undergone steps S301 to S306. The number of times of repetition is not particularly limited. For example, the number of times of repetition may be set in the rating information storage unit 9 and the above steps may be repeated the set number of times. If the number of times of repetition is reached, the process proceeds to step S318.

In step S308, the plurality of spectrum waveforms with the frequency axes aligned, which are collected in step S307, are overlapped and subjected to averaging processing. Thus, the influence of noise or the like can be removed.

As described above, the state diagnosis method for the electric motor 5 includes the steps of: receiving current data detected from the electric motor 5 by the current detector 4; performing frequency analysis on the received current data, to calculate an analysis result; detecting a plurality of peak intensities of sideband waves about the power supply frequency of the electric motor 5 from the analysis result; calculating the natural frequency of the belt gear portion 60 from the rating information of the electric motor and extracting, from the plurality of detected peak intensities, a peak intensity of a sideband wave appearing at a position away by a distance of the natural frequency from the power supply frequency of the electric motor 5 as a reference; and comparing the peak intensity with the peak intensity threshold calculated from the electric motor 5 operating normally, to perform diagnosis for the electric motor 5. Thus, it is possible to perform state diagnosis for the electric motor 5, using one parameter which is the peak intensity of the sideband wave due to the belt gear frequency, and it is not necessary to calculate a plurality of parameters.

FIG. 8 shows comparison of frequency analysis results in a normal case and an abnormal case of the electric motor 5. A solid line indicates an analysis result in a case where the electric motor 5 is normal and a dotted line indicates an analysis result in a case where the electric motor 5 is abnormal. As shown in FIG. 8, when abnormality has occurred in the electric motor 5, peak intensities of sideband waves due to the belt gear frequency increase as compared to a normal case. Therefore, in the state diagnosis device 100 for the electric motor 5 according to the present embodiment, the peak intensity threshold which is a threshold for a peak intensity of a sideband wave due to the belt gear frequency acquired in advance from the electric motor 5 operating normally is used as a threshold for judging whether or not the electric motor 5 is abnormal, and if the peak intensity threshold is satisfied, it is judged that there is abnormality in the electric motor 5, whereby abnormality of the electric motor 5 can be diagnosed.

As described above, the state diagnosis device 100 for the electric motor 5 according to the present embodiment performs frequency analysis on current data acquired from the electric motor 5, and performs state diagnosis for the electric motor 5, using a peak intensity of a sideband wave due to the belt gear frequency extracted by the characteristic peak extraction unit 131 from a spectrum waveform which is an analysis result. Thus, it is possible to perform state diagnosis for the electric motor 5, using one parameter which is the peak intensity of the sideband wave due to the belt gear frequency, as a parameter in diagnosis. As a result, the number of parameters needed in diagnosis decreases, and a time taken for diagnosis can be shortened.

In the present embodiment, the configuration in which the analysis unit 120 includes the peak detection calculation unit 122, the rotational frequency band extraction unit 123, the frequency axis conversion unit 124, and the averaging processing unit 125 has been described. However, the present disclosure is not limited thereto. The frequency analysis unit 121 may perform frequency analysis on current data inputted from the current input unit 7, to calculate a spectrum waveform which is an analysis result, and may output the calculated spectrum waveform to the calculation unit 112. In this case, the analysis unit 120 only has to include the frequency analysis unit 121.

In the above description, it has been described that the state diagnosis device 100 according to the present embodiment diagnoses that there is abnormality in a case where a peak intensity of a sideband wave extracted by the characteristic peak extraction unit 131 satisfies the peak intensity threshold. Here, the method for judging whether or not the peak intensity threshold is satisfied is not limited. For example, it may be judged that there is abnormality in a case where the peak intensity threshold has been satisfied for a certain period or longer. Alternatively, a certain number of times may be set and it may be judged that there is abnormality in a case where the number of times the peak intensity threshold is satisfied exceeds the set number of times.

### Embodiment 2

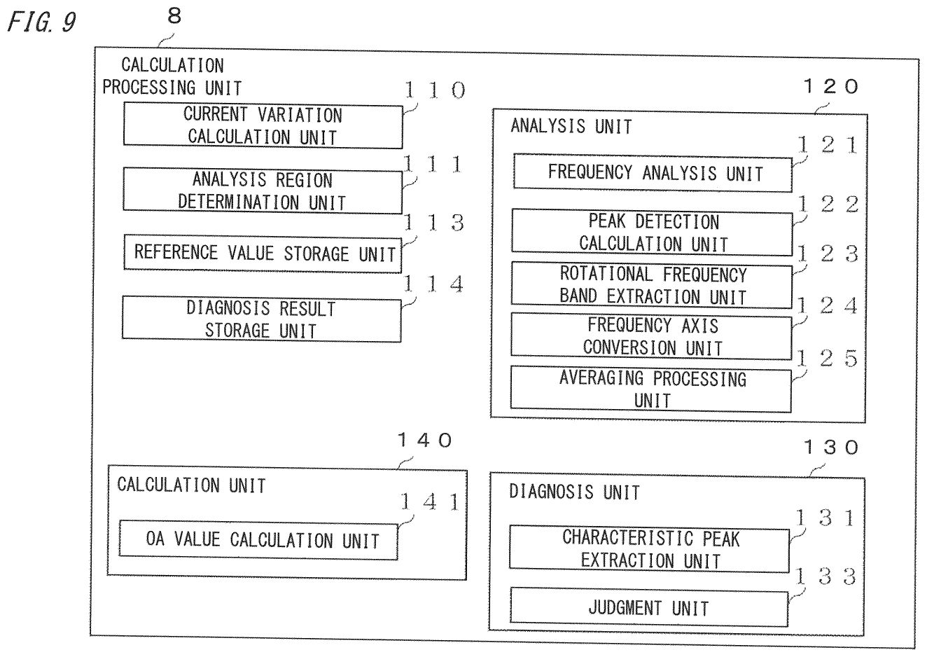

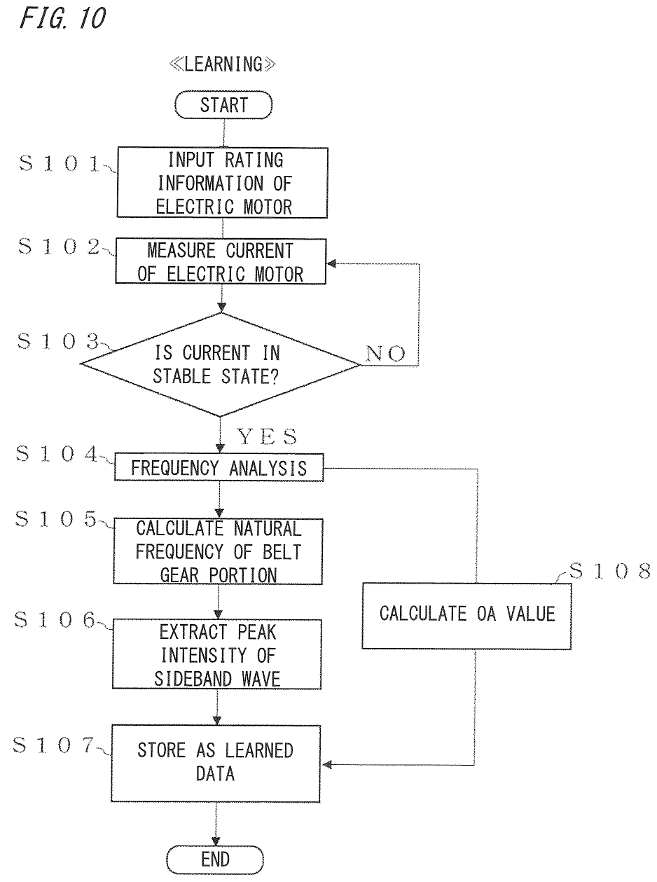

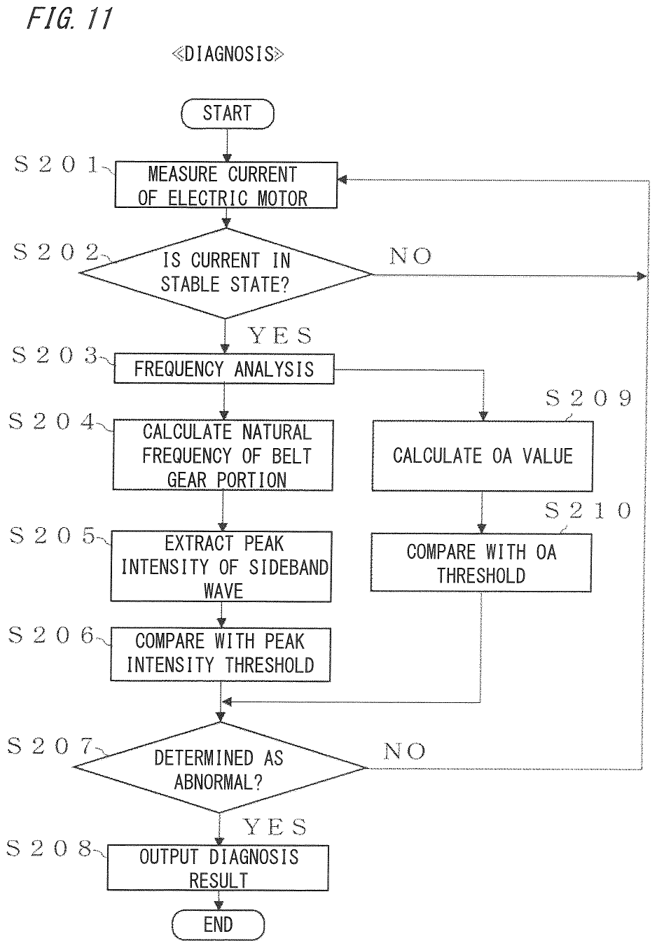

The present embodiment will be described with reference to FIG. 9 to FIG. 11. FIG. 9 shows a configuration of a calculation processing unit 80 of a state diagnosis device for an electric motor according to the present embodiment. FIG. 10 is a flowchart showing a processing procedure in learning of the state diagnosis device for the electric motor according to the present embodiment. FIG. 11 is a flowchart showing a processing procedure in diagnosis by the state diagnosis device for the electric motor according to the present embodiment.

Embodiment 1 has shown the state diagnosis device 100 in which, from a spectrum waveform which is an analysis result calculated by the analysis unit 120, the characteristic peak extraction unit 131 extracts peak intensities of sideband waves appearing at positions away by a distance of the belt gear frequency toward both of low-frequency and high-frequency sides from the power supply frequency, and the diagnosis unit 130 compares the extracted peak intensities of the sideband waves with the peak intensity threshold, to perform state diagnosis for the electric motor 5. The present embodiment shows a state diagnosis device 101 for the electric motor 5 in which a calculation unit 140 includes an OA value calculation unit 141 which calculates an overall value (hereinafter, referred to as “OA value”) to be used at the time of performing state diagnosis for the electric motor 5. The other components are the same as those in embodiment 1, the same components as those in embodiment 1 are denoted by the same reference characters, and the description thereof is omitted.

As shown in FIG. 9, the calculation processing unit 80 of the state diagnosis device 101 includes the current variation calculation unit 110, the analysis region determination unit 111, the reference value storage unit 113, the diagnosis result storage unit 114, the analysis unit 120, the diagnosis unit 130, and the calculation unit 140. With this configuration, the diagnosis unit 130 can perform state diagnosis for the electric motor 5 through comparison between a peak intensity of a sideband wave and the peak intensity threshold. Thus, the number of parameters needed in state diagnosis decreases, and a diagnosis time can be shortened.

Further, the calculation unit 140 of the calculation processing unit 80 according to the present embodiment includes the OA value calculation unit 141.

The OA value calculation unit 141 calculates an OA value which is an average value of amplitudes as information for determining abnormality of the electric motor 5, from a spectrum waveform which is an analysis result calculated by the analysis unit 120. The OA value calculated in learning is stored in the reference value storage unit 113 and the OA value calculated in diagnosis is outputted to a judgment unit 133.

The OA value refers to the average magnitude of amplitudes over the entire spectrum waveform which is an analysis result obtained through frequency analysis on current data. Here, signal intensities at the power supply frequency and harmonic components thereof occupy a large proportion of the calculated OA value. Therefore, peaks of frequency components at the power supply frequency and high-order frequency components that are integer multiples of the power supply frequency, i.e., harmonic components of the power supply frequency, may be excluded from values for the OA value calculated by the OA value calculation unit 141. By excluding values that occupy a large proportion of the OA value as described above, erroneous diagnosis can be prevented.

Next, processing procedures in learning and diagnosis will be described with reference to FIG. 10 and FIG. 11. In FIG. 10, the same processing contents as those in FIG. 5 are denoted by the same reference characters. Similarly, in FIG. 11, the same processing contents as those in FIG. 6 are denoted by the same reference characters. Therefore, step S107 and step S108 in FIG. 10 and step S207, step S209, and step S210 in FIG. 11 will be described below, and the description of the other steps is omitted.

First, the processing procedure in learning will be described. In step S108, the OA value calculation unit 141 calculates an OA value from the spectrum waveform which is an analysis result outputted from the analysis unit 120. The OA value calculated by the OA value calculation unit 141 is outputted to the reference value storage unit 113.

In step S107, the reference value storage unit 113 stores the OA value outputted from the OA value calculation unit 141, as a reference value used in diagnosis, i.e., an OA threshold. In addition, the reference value storage unit 113 stores the peak intensity of the sideband wave due to the belt gear frequency extracted by the characteristic peak extraction unit 131 in step S106, as a reference value used in diagnosis, i.e., the peak intensity threshold. As described above, in step S107, the OA threshold and the peak intensity threshold are stored as learned data in the reference value storage unit 113. The OA threshold and the peak intensity threshold may be stored in the rating information storage unit 9.

Next, the processing procedure in diagnosis will be described. In step S209, the OA value calculation unit 141 calculates an OA value from the spectrum waveform which is an analysis result outputted from the analysis unit 120. The calculated OA value is outputted from the OA value calculation unit 141 to the judgment unit 133 of the diagnosis unit 130.

In step S210, the judgment unit 133 compares the OA value calculated by the OA value calculation unit 141 in step S209 with the OA threshold stored in the reference value storage unit 113.

In step S207, if it is determined that the OA value satisfies the OA threshold in step S210 and it is determined that the peak intensity satisfies the peak intensity threshold in step S206, the judgment unit 133 judges that there is abnormality in the electric motor 5, and the process proceeds to step S208. If one of the OA value or the peak intensity does not satisfy the threshold, the judgment unit 133 judges that the electric motor 5 is normal, and the process returns to step S201.

As described above, the state diagnosis method for the electric motor 5 includes the steps of: receiving current data detected from the electric motor 5 by the current detector 4; performing frequency analysis on the received current data, to calculate an analysis result; detecting a plurality of peak intensities of sideband waves about the power supply frequency of the electric motor 5 from the analysis result; calculating the natural frequency of the belt gear portion 60 from the rating information of the electric motor 5 and extracting, from the plurality of detected peak intensities, a peak intensity of a sideband wave appearing at a position away by a distance of the natural frequency from the power supply frequency of the electric motor 5 as a reference; calculating an OA value from the analysis result; and comparing the peak intensity with the peak intensity threshold calculated from the electric motor 5 operating normally, and comparing the OA value with the OA threshold calculated from the electric motor 5 operating normally, to perform diagnosis for the electric motor 5. Thus, accuracy of a diagnosis result can be improved as compared to the state diagnosis method for the electric motor 5 according to embodiment 1.

As described above, in the state diagnosis device 101 for the electric motor 5 according to the present embodiment, the calculation unit 140 includes the OA value calculation unit 141, and the judgment unit 133 performs state diagnosis for the electric motor 5, using the OA value calculated by the OA value calculation unit 141 and the peak intensity of the sideband wave due to the belt gear frequency extracted by the characteristic peak extraction unit 131. Thus, the number of parameters needed in diagnosis decreases, and a time taken for diagnosis can be shortened. In addition, accuracy of the diagnosis result can be improved as compared to the state diagnosis method for the electric motor 5 according to embodiment 1.

### Embodiment 3

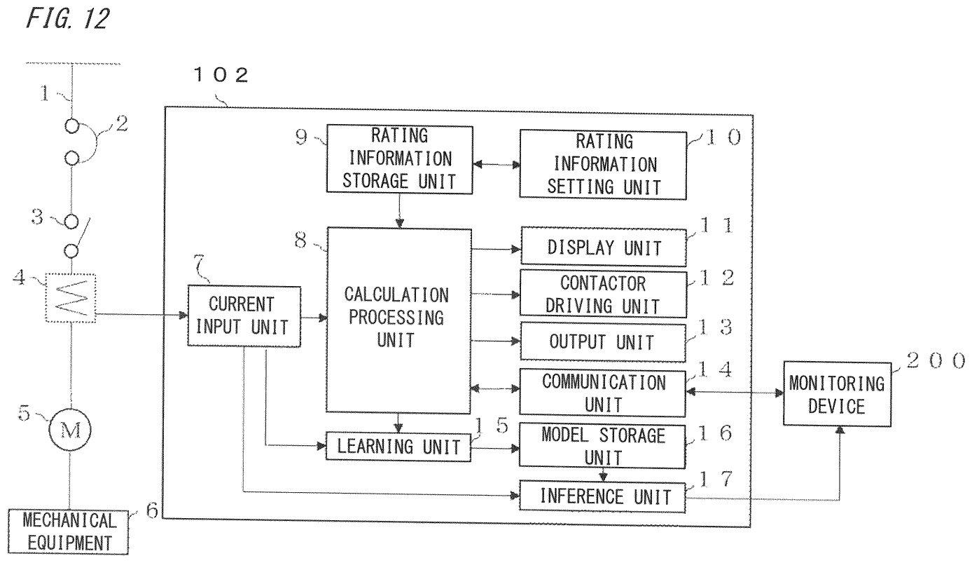

The present embodiment will be described with reference to FIG. 12. FIG. 12 shows an entire system configuration of a state diagnosis device for an electric motor according to the present embodiment.

The present embodiment shows a state diagnosis device 102 for the electric motor 5 configured such that a learning unit 15, a model storage unit 16, and an inference unit 17 are further provided in the state diagnosis device 100 for the electric motor 5 according to embodiment 1. The other components are the same as those in embodiment 1, the same components as those in embodiment 1 are denoted by the same reference characters, and the description thereof is omitted.

As shown in FIG. 11, the state diagnosis device 102 includes the current input unit 7, the calculation processing unit 81, the rating information storage unit 9, the rating information setting unit 10, the display unit 11, the contactor driving unit 12, the output unit 13, the communication unit 14, the learning unit 15, the model storage unit 16, and the inference unit 17, for example.

In the state diagnosis device 102, the characteristic peak extraction unit 131 extracts a peak intensity of a sideband wave due to the belt gear frequency from peak intensities of sideband waves detected from a spectrum waveform by the calculation unit 112, and the extracted peak intensity is compared with the peak intensity threshold, to perform state diagnosis for the electric motor 5. Thus, it is possible to perform abnormality diagnosis for the electric motor 5 using the peak intensity of the sideband wave due to the belt gear frequency as a parameter in diagnosis, whereby the number of parameters needed in diagnosis decreases, and a diagnosis time can be shortened.

The learning unit 15 acquires current data acquired by the current input unit 7 and a diagnosis result for the electric motor 5 stored in the diagnosis result storage unit 114, and performs learning so as to associate the diagnosis result and the current data with each other, to generate a trained model. That is, the diagnosis result stored in the diagnosis result storage unit 114 is stored so as to be associated with current data that has not undergone frequency analysis, and the learning unit 15 learns a time-series pattern indicating a sign of abnormality, on the basis of the diagnosis result, from time-series data of current data acquired from the current input unit 7, to generate a trained model.

In learning for the learning unit 15 to generate a trained model, the following method is used: a time-series pattern that is common in an abnormal case and corresponds to current data not included in a time-series pattern in a normal case is inferred through deep learning from current data in a certain period before the electric motor 5 is determined to be abnormal. Alternatively, known machine learning such as genetic programming, inductive logic programming, or a support vector machine, may be used.

The model storage unit 16 stores the trained model generated by the learning unit 15. The stored trained model is not limited to the trained model generated by the learning unit 15. For example, data that has undergone learning in advance may be read from the outside and stored as a trained model. The model storage unit 16 may be provided in an external server or the like, instead of being provided in the state diagnosis device 102.

The inference unit 17 infers an abnormality sign of the electric motor 5 from current data newly acquired from the current input unit 7, using the trained model stored in the model storage unit 16, and outputs an inference result to the monitoring device 200. That is, the inference unit 17 acquires current data from the current input unit 7, and infers whether or not the current data corresponds to a time-series pattern found as a sign in an abnormal case of the electric motor 5, using the trained model stored in the model storage unit 16. If there is a sign of abnormality, the inference unit 17 judges that there is abnormality in the electric motor 5, and outputs an inference result to the monitoring device 200.

Instead of being outputted to the monitoring device 200, the inference result may be outputted to the display unit 11, the contactor driving unit 12, the output unit 13, and the communication unit 14 via the calculation processing unit 8. By finding a sign of abnormality of the electric motor 5 from the current data as described above, it is possible to perform maintenance of the electric motor 5 in a planned manner, whereby the stop period of the mechanical equipment 6 connected to the electric motor 5 can be adjusted so that the stop period becomes shortest.

As described above, the state diagnosis device 102 for the electric motor 5 according to the present embodiment further includes the learning unit 15, the model storage unit 16, and the inference unit 17. The learning unit 15 generates a trained model from current data acquired on the basis of an analysis result, and the inference unit 17 infers abnormality of the electric motor 5 from the current data using the trained model. With this configuration, abnormality of the electric motor 5 can be predicted from current data, whereby it is possible to perform sound operation of the electric motor 5 and execute a maintenance plan without unnecessarily stopping equipment.

The present embodiment has shown the state diagnosis device 102 configured such that the learning unit 15, the model storage unit 16, and the inference unit 17 are further included in the state diagnosis device 100 of embodiment 1. However, a configuration of further including the learning unit 15, the model storage unit 16, and the inference unit 17 in the state diagnosis device 101 of embodiment 2 is also possible.

### Embodiment 4

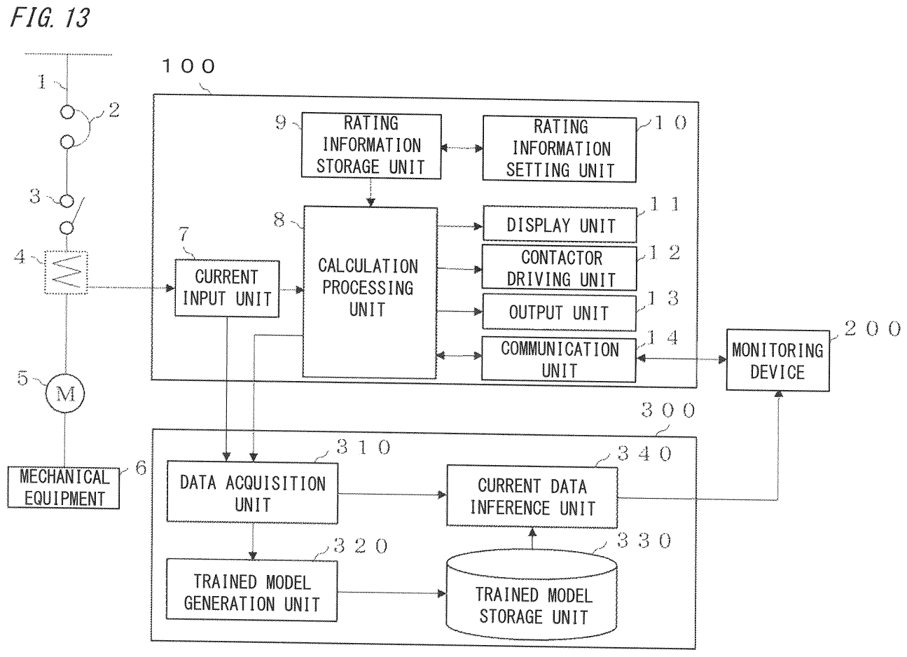

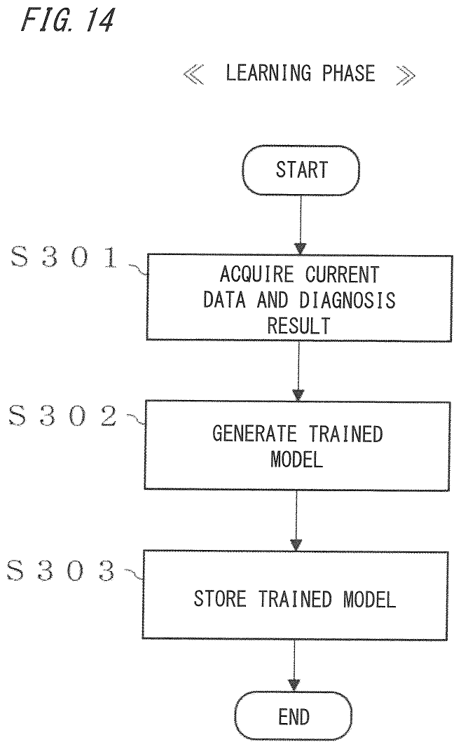

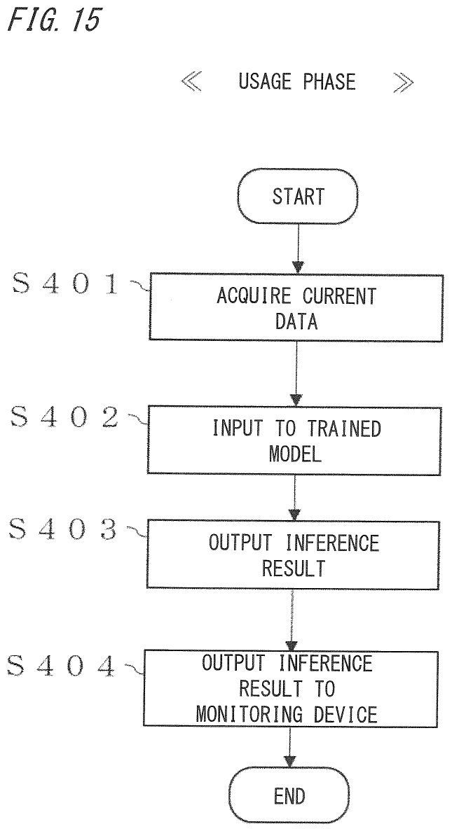

The present embodiment will be described with reference to FIG. 13 to FIG. 15. FIG. 13 shows an entire system configuration of an abnormality sign inference device for an electric motor according to the present embodiment. FIG. 14 is a flowchart showing a processing procedure in learning of the abnormality sign inference device for the electric motor according to the present embodiment. FIG. 15 is a flowchart showing a processing procedure in usage of the abnormality sign inference device for the electric motor according to the present embodiment.

The present embodiment shows an abnormality sign inference device 300 for the electric motor 5, which is externally provided to the state diagnosis device 100 for the electric motor 5. The other components are the same as those in embodiment 1, the same components as those in embodiment 1 are denoted by the same reference characters, and the description thereof is omitted.

As shown in FIG. 13, the state diagnosis device 100 includes the current input unit 7, the calculation processing unit 8, the rating information storage unit 9, the rating information setting unit 10, the display unit 11, the contactor driving unit 12, the output unit 13, and the communication unit 14, for example. In the state diagnosis device 100, the characteristic peak extraction unit 131 extracts a peak intensity of a sideband wave due to the belt gear frequency from peak intensities of sideband waves detected from a spectrum waveform by the calculation unit 112, and the extracted peak intensity is compared with the peak intensity threshold, to perform state diagnosis for the electric motor 5. Thus, it is possible to perform abnormality diagnosis for the electric motor 5 using the peak intensity of the sideband wave due to the belt gear frequency as a parameter in diagnosis, whereby the number of parameters needed in diagnosis decreases, and a diagnosis time can be shortened.

The abnormality sign inference device 300 for the electric motor 5 includes a data acquisition unit 310, a trained model generation unit 320, a trained model storage unit 330, and a current data inference unit 340.

The data acquisition unit 310 acquires current data from the current input unit 7 of the state diagnosis device 100, and acquires a diagnosis result for the electric motor 5 associated with current data that has not undergone frequency analysis, from the diagnosis result storage unit 114 of the calculation processing unit 8.

The trained model generation unit 320 learns the current data acquired by the data acquisition unit 310 on the basis of the diagnosis result, to generate a trained model. Specifically, from time-series data of the current data acquired by the current input unit 7, the trained model generation unit 320 learns a time-series pattern indicating a sign of abnormality on the basis of a diagnosis result, to generate a trained model. The number of data to be learned for a trained model is not particularly limited. For example, the number of data to be learned may be set in advance in the trained model generation unit 320 or the like, and learning may be finished when learning of the set number of data is completed.

In learning to generate a trained model, the following method is used: a time-series pattern that is common in an abnormal case and corresponds to current data not included in a time-series pattern in a normal case is inferred through deep learning from current data in a certain period before the electric motor 5 is determined to be abnormal. Instead of deep learning, known machine learning such as genetic programming, inductive logic programming, or a support vector machine, may be used.

The trained model storage unit 330 stores the trained model generated by the trained model generation unit 320. The stored trained model is not limited to the trained model generated by the trained model generation unit 320. For example, learned data may be read from the outside and stored as a trained model. The trained model storage unit 330 may be provided in an external server, for example, instead of being provided in the abnormality sign inference device 300.

The current data inference unit 340 infers an abnormality sign of the electric motor 5 from current data newly acquired from the data acquisition unit 310, using the trained model, and outputs an inference result to the monitoring device 200. That is, the data acquisition unit 310 acquires current data from the current input unit 7, and the current data inference unit 340 infers whether or not the acquired current data corresponds to a time-series pattern found as a sign in an abnormal case of the electric motor 5, using the trained model stored in the trained model storage unit 330. If there is a sign of abnormality, the current data inference unit 340 judges that there is abnormality in the electric motor 5, and outputs an inference result to the monitoring device 200.

Instead of being outputted to the monitoring device 200, the inference result may be outputted to the display unit 11, the contactor driving unit 12, the output unit 13, and the communication unit 14 via the calculation processing unit 8. By finding a sign of abnormality of the electric motor 5 from the current data as described above, it is possible to perform maintenance of the electric motor 5 in a planned manner, whereby the stop period of the mechanical equipment 6 connected to the electric motor 5 can be adjusted so that the stop period becomes shortest.

Next, a learning procedure will be described with reference to FIG. 14. FIG. 14 is a flowchart showing a learning phase.

In step S301, the data acquisition unit 310 acquires current data from the current input unit 7, and acquires a diagnosis result associated with current data that has not undergone frequency analysis, from the diagnosis result storage unit 114 of the calculation processing unit 8.

In step S302, the trained model generation unit 320 learns an abnormality sign of the electric motor 5 on the basis of the current data and the diagnosis result outputted from the data acquisition unit 310. That is, from current data acquired from the current input unit 7 in a certain period before the electric motor 5 is diagnosed as abnormal, the trained model generation unit 320 learns a time-series pattern of the current data that is common in a case of being diagnosed as abnormal, on the basis of a diagnosis result, to generate a trained model.

In step S303, the trained model storage unit 330 stores the trained model generated in step S302.

Next, a usage procedure will be described with reference to FIG. 15. FIG. 15 is a flowchart showing a usage phase.

In step S401, the data acquisition unit 310 acquires current data from the current input unit 7.

In step S402, the current data acquired by the data acquisition unit 310 in step S401 is inputted to the trained model stored in the trained model storage unit 330.

In step S403, the current data inference unit 340 outputs an inference result based on the current data inputted to the trained model, i.e., a result obtained by inferring whether or not there is a sign of abnormality in the electric motor 5 from the current data acquired from the data acquisition unit 310.

In step S404, the inference result outputted from the current data inference unit 340 is outputted to the monitoring device 200. Instead of being outputted to the monitoring device 200, the inference result may be outputted to the display unit 11, the contactor driving unit 12, the output unit 13, and the communication unit 14 via the calculation processing unit 8.

As described above, the abnormality sign inference device 300 for the electric motor 5 according to the present embodiment learns current data acquired from the state diagnosis device 100 on the basis of a diagnosis result, to generate a trained model, and inputs newly acquired current data to the trained model, to infer an abnormality sign of the electric motor 5. Thus, before the state diagnosis device 100 for the electric motor 5 diagnoses that there is abnormality in the electric motor 5, the abnormality sign inference device 300 infers an abnormality sign from current data and outputs presence/absence of an abnormality sign to the monitoring device 200, whereby it is possible to perform maintenance of the electric motor 5 in a planned manner. In addition, by making a maintenance plan in advance, it is possible to shorten an unnecessary stop period of the mechanical equipment 6 connected to the electric motor 5.

In the present embodiment, the configuration is made such that a trained model is generated from current data and a diagnosis result acquired from the state diagnosis device 100 of embodiment 1 and newly acquired current data is inputted to the trained model, to infer an abnormality sign of the electric motor 5. However, the configuration may be made such that a trained model is generated from current data and a diagnosis result acquired from the state diagnosis device 101 of embodiment 2 and newly acquired current data is inputted to the trained model, to infer an abnormality sign of the electric motor 5.

### DESCRIPTION OF THE REFERENCE CHARACTERS

1 main circuit
2 circuit breaker
3 electromagnetic contactor
4 current detector
5 electric motor
6 mechanical equipment
7 current input unit
8, 80 calculation processing unit
9 rating information storage unit
10 rating information setting unit
11 display unit
12 contactor driving unit
13 output unit
14 communication unit
15 learning unit
16 model storage unit
17 inference unit
20 processor
30 memory
40 display
50 input interface
60 belt gear portion
70 load equipment
100, 101 state diagnosis device
110 current variation calculation unit
111 analysis region determination unit
112, 140 calculation unit
113 reference value storage unit
114 diagnosis result storage unit
120 analysis unit
121 frequency analysis unit
122 peak detection calculation unit
123 rotational frequency band extraction unit
124 frequency axis conversion unit
125 averaging processing unit
130 diagnosis unit
131 characteristic peak extraction unit
132, 133 judgment unit
141 OA value calculation unit
200 monitoring device
300 abnormality sign inference device
310 data acquisition unit
320 trained model generation unit
330 trained model storage unit
340 current data inference unit

1. A state diagnosis device for an electric motor, comprising:
a current input circuitry which receives current data detected from the electric motor by a current detector;
an analysis circuitry which performs frequency analysis on the current data received from the current input circuitry, to calculate an analysis result;
a calculation circuitry which detects a plurality of peak intensities of sideband waves about a power supply frequency of the electric motor, from the analysis result;
a characteristic peak extraction circuitry which calculates a natural frequency of a belt gear portion from rating information of the electric motor, and extracts, from the plurality of peak intensities detected by the calculation circuitry, the peak intensity of the sideband wave appearing at a position away by a distance of the natural frequency from the power supply frequency of the electric motor as a reference; and
a judgment circuitry which compares the peak intensity extracted by the characteristic peak extraction circuitry with a peak intensity threshold calculated from the electric motor operating normally, to perform diagnosis for the electric motor.

2. The state diagnosis device for the electric motor according to claim 1, wherein
the analysis circuitry includes
a frequency analysis circuitry which performs the frequency analysis on the current data,
a peak detection calculation circuitry which detects a plurality of peak intensities of sideband waves about the power supply frequency of the electric motor from a spectrum waveform which is a frequency analysis result of the frequency analysis circuitry,
a rotational frequency band extraction circuitry which calculates a rotational frequency from the rating information of the electric motor and extracts, from the plurality of peak intensities detected by the peak detection calculation circuitry, the peak intensity of the sideband wave appearing at a position away by a distance of the rotational frequency from the power supply frequency of the electric motor as a reference,
a frequency axis conversion circuitry which calculates a correction value for aligning the frequency axis of each of the spectrum waveforms and corrects each of the spectrum waveforms, and
an averaging processing circuitry which performs averaging processing on a plurality of the spectrum waveforms corrected by the frequency axis conversion circuitry,
thus calculating the analysis result.

3. The state diagnosis device for the electric motor according to claim 1, wherein
the analysis circuitry performs the frequency analysis in an analysis region where the current data is determined to be in a stable state.

4. The state diagnosis device for the electric motor according to claim 3, wherein
the analysis circuitry performs the frequency analysis on the current data in the analysis region extracted by
a current variation calculation circuitry which calculates whether or not the current data is in the stable state, and
an analysis region determination circuitry which performs determination by comparing a calculation result of the current variation calculation circuitry with a region determination threshold calculated in advance from the electric motor operating normally.

5. The state diagnosis device for the electric motor according to claim 1, wherein
the calculation circuitry includes an OA value calculation circuitry which calculates an OA value which is an average value of amplitudes, from the analysis result calculated by the analysis circuitry.

6. The state diagnosis device for the electric motor according to claim 5, wherein
the judgment circuitry compares the OA value calculated by the OA value calculation circuitry with an OA threshold calculated from the electric motor operating normally, to perform diagnosis for the electric motor.

7. The state diagnosis device for the electric motor according to claim 1, further comprising:
a learning circuitry which acquires the current data acquired by the current input circuitry and a diagnosis result for the electric motor, and performs learning so as to associate the diagnosis result and the current data with each other, to generate a trained model; and
an inference circuitry which infers an abnormality sign of the electric motor from the current data newly acquired from the current input circuitry, using the trained model, and outputs an inference result.

8. An abnormality sign inference device for an electric motor, comprising:
a data acquisition circuitry which acquires current data and a diagnosis result for the electric motor associated with current data that has not undergone frequency analysis, from the state diagnosis device for the electric motor according to claim 1;
a trained model generation circuitry which learns the current data acquired by the data acquisition circuitry on the basis of the diagnosis result, to generate a trained model; and
a current data inference circuitry which infers an abnormality sign of the electric motor from the current data newly acquired from the data acquisition circuitry, using the trained model, and outputs an inference result.

9. A state diagnosis method for an electric motor, comprising the steps of:
receiving current data detected from an electric motor by a current detector;
performing frequency analysis on the received current data, to calculate an analysis result;
detecting a plurality of peak intensities of sideband waves about a power supply frequency of the electric motor, from the analysis result;
calculating a natural frequency of a belt gear portion from rating information of the electric motor, and extracting, from the plurality of detected peak intensities, the peak intensity of the sideband wave appearing at a position away by a distance of the natural frequency from the power supply frequency of the electric motor as a reference; and
comparing the peak intensity with a peak intensity threshold calculated from the electric motor operating normally, to perform diagnosis for the electric motor.

10. The state diagnosis device for the electric motor according to claim 2, wherein
the analysis circuitry performs the frequency analysis in an analysis region where the current data is determined to be in a stable state.

11. The state diagnosis device for the electric motor according to claim 10, wherein
the analysis circuitry performs the frequency analysis on the current data in the analysis region extracted by
a current variation calculation circuitry which calculates whether or not the current data is in the stable state, and
an analysis region determination circuitry which performs determination by comparing a calculation result of the current variation calculation circuitry with a region determination threshold calculated in advance from the electric motor operating normally.

12. The state diagnosis device for the electric motor according to claim 2, wherein
the calculation circuitry includes an OA value calculation circuitry which calculates an OA value which is an average value of amplitudes, from the analysis result calculated by the analysis circuitry.

13. The state diagnosis device for the electric motor according to claim 3, wherein
the calculation circuitry includes an OA value calculation circuitry which calculates an OA value which is an average value of amplitudes, from the analysis result calculated by the analysis circuitry.

14. The state diagnosis device for the electric motor according to claim 4, wherein
the calculation circuitry includes an OA value calculation circuitry which calculates an OA value which is an average value of amplitudes, from the analysis result calculated by the analysis circuitry.

15. The state diagnosis device for the electric motor according to claim 10, wherein
the calculation circuitry includes an OA value calculation circuitry which calculates an OA value which is an average value of amplitudes, from the analysis result calculated by the analysis circuitry.

16. The state diagnosis device for the electric motor according to claim 11, wherein
the calculation circuitry includes an OA value calculation circuitry which calculates an OA value which is an average value of amplitudes, from the analysis result calculated by the analysis circuitry.

17. The state diagnosis device for the electric motor according to claim 12, wherein
the judgment circuitry compares the OA value calculated by the OA value calculation circuitry with an OA threshold calculated from the electric motor operating normally, to perform diagnosis for the electric motor.

18. The state diagnosis device for the electric motor according to claim 13, wherein
the judgment circuitry compares the OA value calculated by the OA value calculation circuitry with an OA threshold calculated from the electric motor operating normally, to perform diagnosis for the electric motor.

19. The state diagnosis device for the electric motor according to claim 14, wherein
the judgment circuitry compares the OA value calculated by the OA value calculation circuitry with an OA threshold calculated from the electric motor operating normally, to perform diagnosis for the electric motor.

20. The state diagnosis device for the electric motor according to claim 15, wherein
the judgment circuitry compares the OA value calculated by the OA value calculation circuitry with an OA threshold calculated from the electric motor operating normally, to perform diagnosis for the electric motor.
